(19) United States
(12) Patent Application Publication
(10) Pub. No.: US 2026/0307527 A1
(43) Pub. Date: Oct. 8, 2026

(54) MANAGEMENT SYSTEM FOR WORK MACHINE AND MANAGEMENT METHOD FOR WORK MACHINE

(71) Applicant: KOMATSU LTD., Tokyo (JP)

(72) Inventor: Ryoichi TOGASHI, Tokyo (JP)

(73) Assignee: KOMATSU LTD., Tokyo (JP)

(21) Appl. No.: 19/481,871

(22) PCT Filed: Mar. 29, 2024
(86) PCT No.: PCT/JP2024/013224

§ 371 Date: Nov. 5, 2025

(30) Foreign Application Priority Data
May 8, 2023 (JP) 2023-076884

(51) Int. Cl. B60L 53/68; B60L 53/66; G01R 21/00

(52) U.S. Cl. CPC B60L 53/68; B60L 53/665; G01R 21/007

(57) ABSTRACT

A management system 1 for a work machine 2 includes a processor 48. The processor 48 calculates a usage amount of electric power used to charge a battery 31 of the work machine 2, and causes a storage device 50 to store the usage amount. The electric power includes one or both of first electric power for emitting a first amount of carbon dioxide to generate a unit amount of electric power, and second electric power for emitting a second amount of carbon dioxide smaller than the first amount to generate a unit amount of electric power. The usage amount includes a first usage amount representing a usage amount of the first electric power used to charge the battery, and a second usage amount representing a usage amount of the second electric power used to charge the battery.

### TECHNICAL FIELD

The present disclosure relates to a management system for a work machine and a management method for the work machine.

### BACKGROUND ART

Patent Document 1 discloses a technique of charging a battery of a vehicle.

### CITATION LIST

### Patent Literature Patent Document 1: JP 2022-510390 A

### SUMMARY OF INVENTION

### Technical Problem

From a viewpoint of prevention of global warming, it is demanded to suppress emission of greenhouse gases. To prevent global warming, work machines including large-capacity batteries have been proposed in a technical field related to work machines. In a case where electric power used by a work machine is generated using fossil fuel energy, use of a work machine including a large-capacity battery may emit greenhouse gas a result. It is necessary to grasp how much greenhouse gas is emitted due to use of a work machine including a large-capacity battery.

An object of the present disclosure is to grasp how much greenhouse gas is emitted due to use of a work machine including a large-capacity battery.

### Solution to Problem

According to the present disclosure, a management system for a work machine is provided. The management system for the work machine includes a processor. The processor calculates a usage amount of electric power used to charge a battery of the work machine, and causes a storage device to store the usage amount. The electric power used to charge the battery includes one or both of first electric power for emitting a first amount of carbon dioxide to generate a unit amount of electric power, and second electric power for emitting a second amount of carbon dioxide smaller than the first amount to generate a unit amount of electric power. The usage amount of electric power includes a first usage amount representing a usage amount of the first electric power used to charge the battery, and a second usage amount representing a usage amount of the second electric power used to charge the battery.

### Advantageous Effects of Invention

According to the present disclosure, it is possible to grasp how much greenhouse gas is emitted due to use of a work machine including a large-capacity battery.

### BRIEF DESCRIPTION OF DRAWINGS

FIG. 1 is a view illustrating a management system for work machines according to an embodiment.

FIG. 2 is a view illustrating an excavator according to the embodiment.

FIG. 3 is a view illustrating a control system of the excavator according to the embodiment.

FIG. 4 is a view illustrating a relationship between power plants and charging stations according to the embodiment.

FIG. 5 is a view illustrating an example of power generation result data according to the embodiment.

FIG. 6 is a block diagram illustrating an in-vehicle controller according to the embodiment.

FIG. 7 is a flowchart illustrating a method for calculating an emission amount of carbon dioxide due to charging of a battery according to the embodiment.

### DESCRIPTION OF EMBODIMENTS

Hereinafter, an embodiment according to the present disclosure will be described with reference to the drawings, but the present disclosure is not limited to the embodiment. Components of the embodiment described below can be combined as appropriate. Furthermore, some components are not used in some cases.

### Overview of Management System

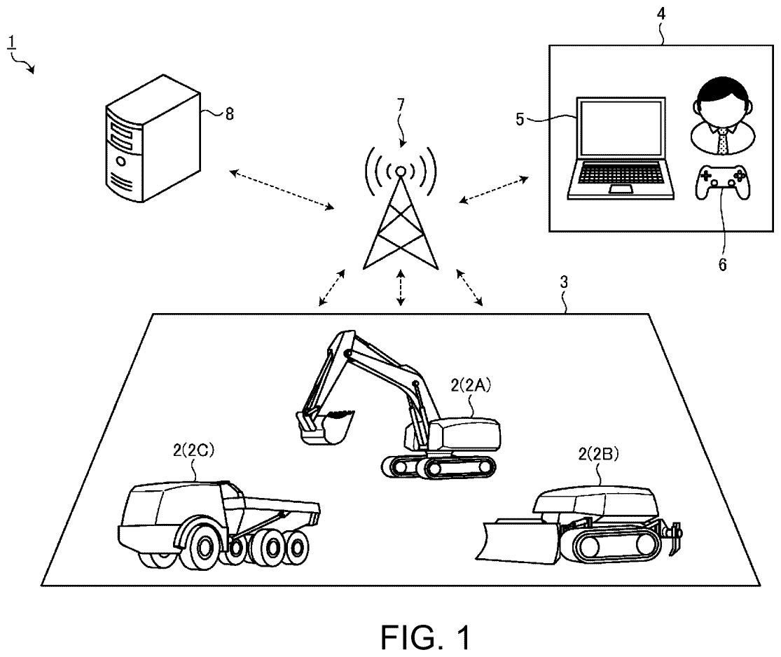

FIG. 1 is a view illustrating a management system 1 for work machines 2 according to the embodiment. The management system 1 manages the work machines 2 operating at a work site 3. In the embodiment, the work machine 2 is an electric work machine that uses a battery pack and an electric motor as a power source. There are a plurality of the work machines 2 at the work site 3. In the example illustrated in FIG. 1, the work machines 2 present at the work site 3 include an excavator 2A, a bulldozer 2B, and a dump truck 2C.

In the embodiment, operators do not board the work machines 2. The work machines 2 are remotely operated. A remote operation room 4 is installed outside the work machines 2. The remote operation room 4 is installed at a remote location of the work site 3. An information terminal 5 and a remote operation device 6 for remotely operating the work machines 2 are each arranged in the remote operation room 4. Each of the information terminal 5 and the remote operation device 6 is present outside the work machines 2. The information terminal 5 includes a computer system disposed in the remote operation room 4.

The remote operation device 6 is operated by an operator in the remote operation room 4. The remote operation device 6 is operated by the operator, thereby generating operation signals for remotely operating the work machines 2. The operation signals generated in the remote operation device 6 are input to the information terminal 5. The information terminal 5 generates a remote operation command on the basis of the operation signals from the remote operation device 6. The information terminal 5 transmits the remote operation command to the work machines 2 via a communication system 7.

The work machines 2 operate on the basis of the remote operation command transmitted from the information terminal 5 present outside the work machines 2. At least one of the work machines 2 or the work site 3 is provided with a camera that acquires image data of the work site 3. The image data of the work site 3 is transmitted to the information terminal 5 via the communication system 7 and displayed on a display device of the information terminal 5. The operator can operate the remote operation device 6 while checking the image data of the work site 3.

The communication system 7 may include a public communication line or may include a dedicated communication line. The communication system 7 is exemplified by a mobile phone communication network or a satellite communication network. Note that the communication system 7 may include the Internet or may include a local area network.

The management system 1 includes a management server 8. The management server 8 includes a computer system. The management server 8 can communicate with the work machines 2 via the communication system 7. The management server 8 collects operation data of the work machines 2. The management server 8 outputs control commands to the work machines 2.

### Work Machine

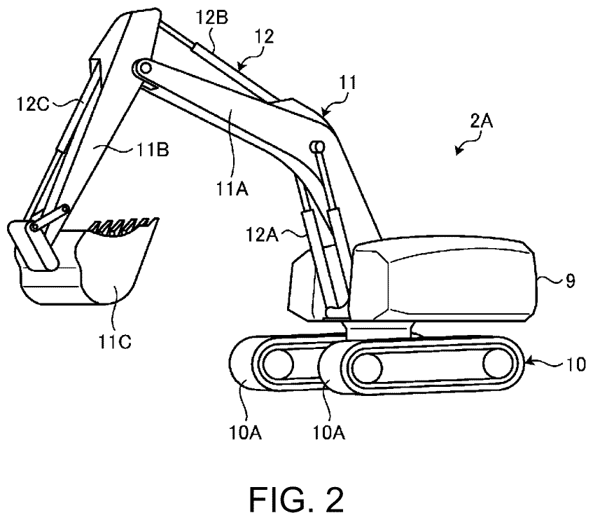

FIG. 2 is a view illustrating the excavator 2A according to the embodiment viewed from a left front side. The excavator 2A includes a revolving body 9, a traveling body 10, a work implement 11, and a work implement cylinder 12.

The revolving body 9 is a vehicle body of the excavator 2A. The traveling body 10 is a traveling device of the excavator 2A. The traveling body 10 supports the revolving body 9. The revolving body 9 is revolvably supported by the traveling body 10. The revolving body 9 is disposed above the traveling body 10. The traveling body 10 travels while supporting the revolving body 9. The traveling body 10 includes a pair of crawler tracks 10A. Rotation of the crawler tracks 10A causes the excavator 2A to travel.

The work implement 11 is coupled to a front portion of the revolving body 9. The work implement 11 includes a boom 11A coupled to the front portion of the revolving body 9, an arm 11B coupled to the boom 11A, and a bucket 11C coupled to the arm 11B. The work implement cylinder 12 includes a boom cylinder 12A that operates the boom 11A, an arm cylinder 12B that operates the arm 11B, and a bucket cylinder 12C that operates the bucket 11C.

### Control System

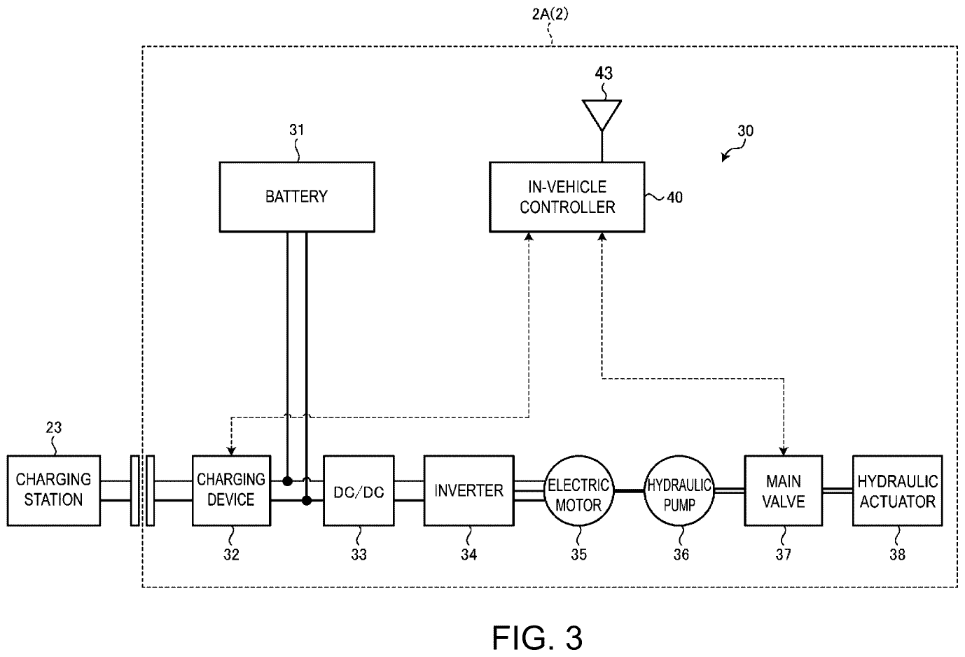

FIG. 3 is a view illustrating a control system 30 of the excavator 2A according to the embodiment. The excavator 2A includes the control system 30. The control system 30 includes a battery 31, a charging device 32, a DC/DC converter 33, an inverter 34, an electric motor 35, a hydraulic pump 36, a main valve 37, a hydraulic actuator 38, an in-vehicle controller 40, and a communication device 43.

The battery 31 is a built-in battery mounted on the work machine 2. The battery 31 includes a secondary battery. In the embodiment, the battery 31 includes a Lithium ion Battery (LiB).

The charging device 32 is connected to a charging station 23 provided outside the work machine 2. The charging station 23 charges the battery 31 using a commercial power supply. The charging device 32 includes an AC/DC converter. The charging device 32 charges the battery 31 with electric power supplied from the charging station 23.

The DC/DC converter 33 boosts a voltage from the battery 31. The DC/DC converter 33 supplies to the inverter 34 a direct current from the battery 31.

The inverter 34 converts the direct current from the DC/DC converter 33 into three-phase alternating current and supplies the direct current to the electric motor 35. The electric motor 35 is driven on the basis of the three-phase alternating current supplied from the inverter 34.

The electric motor 35 is a power source of the work machine 2. The electric motor 35 is driven by electric power from the battery 31.

The hydraulic pump 36 is driven by the electric motor 35. The hydraulic pump 36 discharges hydraulic oil. The hydraulic oil discharged from the hydraulic pump 36 is supplied to the hydraulic actuator 38 via the main valve 37. The hydraulic actuator 38 of the excavator 2A includes the work implement cylinder 12.

Note that, instead of the hydraulic actuator 38, an electric actuator may be provided to the excavator 2A. The work implement cylinder 12 may be an electric cylinder. When an electric actuator is provided to the excavator 2A instead of the hydraulic actuator 38, the hydraulic pump 36 and the main valve 37 are omitted.

The in-vehicle controller 40 includes a computer system. The communication device 43 is connected to the in-vehicle controller 40. The communication device 43 performs wireless communication with the management server 8.

### Power Generation Result Data

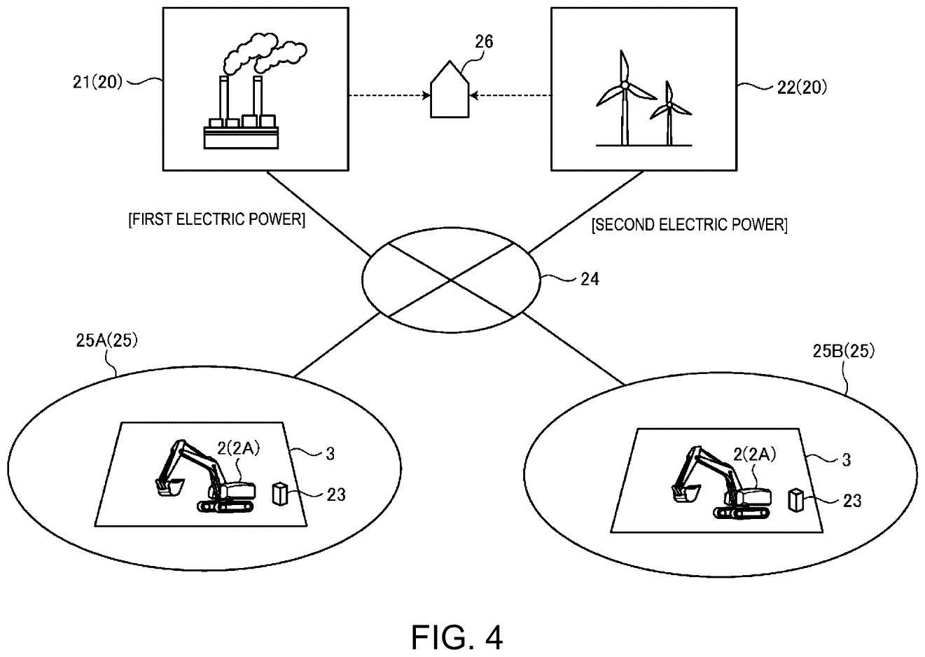

FIG. 4 is a view illustrating a relationship between power plants 20 and the charging stations 23 according to the embodiment. The electric power generated at the power plant 20 is supplied to the charging station 23 via a power transmission facility 24. The power transmission facility 24 supplies electric power to a power supply area 25 in which the charging station 23 is present. There are a plurality of the power plants 20. There are a plurality of the power supply areas 25. In the example illustrated in FIG. 4, the power plant 20 includes a first power plant 21 and a second power plant 22. The power supply area 25 includes a first area 25A and a second area 25B. When the power supply area 25 is located in Japan, the first area 25A is, for example, the Kanto region, and the second area 25B is, for example, the Tohoku region.

The charging station 23 charges the battery 31 using electric power of the commercial power supply. The charging stations 23 are present in the first area 25A and the second area 25B. The work sites 3 are present in the first area 25A and the second area 25B. The charging stations 23 may be present in the work sites 3 or may be present outside the work sites 3. The work machine 2 operates by consuming the electric power generated at the power plant 20.

In the embodiment, consuming at the work machine 2 the electric power generated at the power plant 20 includes consuming the electric power of the battery 31 charged with the electric power generated at the power plant 20. Note that the electric power generated at the power plant 20 may be directly consumed by the work machine 2 without being used to charge the battery 31.

In the embodiment, the electric power consumed by the work machine 2 includes one or both of first electric power and second electric power. The first electric power is electric power for emitting a first amount of carbon dioxide to generate a unit amount of electric power. The second electric power is electric power for emitting a second amount of carbon dioxide smaller than the first amount to generate a unit amount of electric power. The unit amount is a predetermined amount. That is, the amount of carbon dioxide emitted at the time of power generation of the second electric power is smaller than the amount of carbon dioxide emitted at the time of power generation of the first electric power.

The first electric power is electric power generated using exhaustible energy. The exhaustible energy is energy generated using resources whose reserves are finite. The exhaustible energy includes fossil fuel energy such as oil, coal, and natural gas. When the first electric power is generated using the exhaustible energy, carbon dioxide is emitted.

The second electric power is electric power generated using renewable energy. The renewable energy is energy that is always present in nature. The renewable energy includes natural energy such as sunlight, wind power, and water power. When the second electric power is generated using renewable energy, carbon dioxide is not emitted.

In the example illustrated in FIG. 4, the first electric power is generated at the first power plant 21. The second electric power is generated at the second power plant 22. The power transmission facility 24 supplies one or both of the first electric power from the first power plant 21 and the second electric power from the second power plant 22 to the charging station 23. To the charging station 23, both of the first electric power generated at the first power plant 21 and the second electric power generated at the second power plant may be supplied. That is, to the charging station 23, a first ratio (A %) of the first electric power is supplied, and a second ratio (B %) of the second electric power is supplied. Each of A and B represents a real number of 0 or more and 100 or less. A total value of A and B is 100. The electric power used to charge the battery 31 includes A % of the first electric power and B % of the second electric power. From the viewpoint of prevention of global warming, the electric power used to charge the battery 31 is more preferably the second electric power than the first electric power. From the viewpoint of prevention of global warming, the electric power consumed by the work machine 2 is more preferably the second electric power than the first electric power.

Power generation result data related to the electric power supplied to the charging station 23 is announced from an announcement agency 26. As the announcement agency 26, a power transmission company that manages the power plants 20 is exemplified. Note that the announcement agency 26 may be an administrative agency. The announcement agency 26 announces the power generation amount of the first electric power and the power generation amount of the second electric power supplied from the power plants 20 to the power supply areas 25.

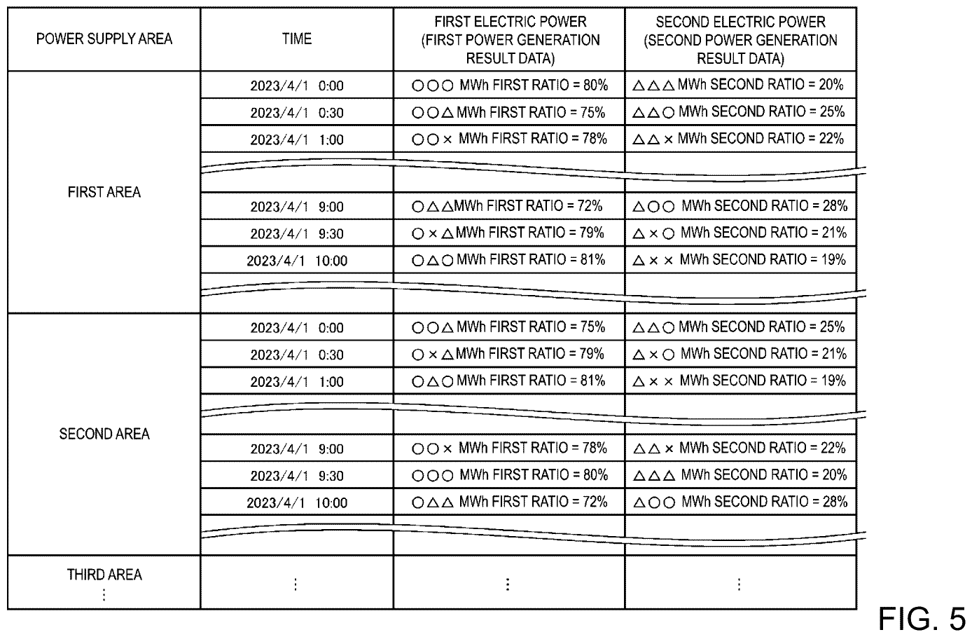

FIG. 5 is a view illustrating an example of power generation result data according to the embodiment. The power generation result data includes first power generation result data representing a power generation result of the first electric power, and second power generation result data representing a power generation result of the second electric power. The first power generation result data represents, for each past time interval, a result value of the power generation amount generated using the exhaustible energy. The second power generation result data represents, for each past time interval, a result value of the power generation amount generated using the renewable energy. Furthermore, the first power generation result data represents the first ratio (A %) of the first electric power, and the second power generation result data represents the second ratio (B %) of the second electric power.

As illustrated in FIG. 5, the result value of the power generation amount may fluctuate per time interval. The first ratio and the second ratio may fluctuate per time interval.

### In-Vehicle Controller

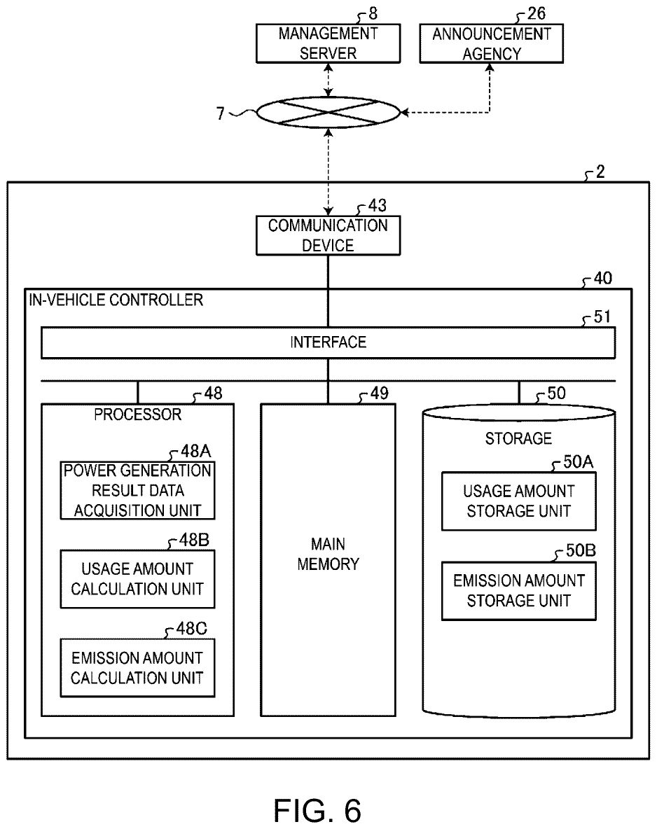

FIG. 6 is a block diagram illustrating the in-vehicle controller 40 according to the embodiment. The management server 8 and the in-vehicle controller 40 each include a computer system. The in-vehicle controller 40 includes a processor 48 such as a Central Processing Unit (CPU), a main memory 49 including a non-volatile memory such as a Read Only Memory (ROM) and a volatile memory such as a Random Access Memory (RAM), a storage 50, and an interface 51 including an input/output circuit. Functions of the in-vehicle controller 40 are stored as a computer program in the storage 50. The processor 48 reads out the computer program from the storage 50, deploys the computer program into the main memory 49, and executes the processing in accordance with the computer program. Note that the computer program may be distributed to the management server 8 via a network.

Similarly, the management server 8 includes a processor, a main memory, a storage, and an interface.

The processor 48 includes a power generation result data acquisition unit 48A, a usage amount calculation unit 48B, and an emission amount calculation unit 48C.

The power generation result data acquisition unit 48A acquires the power generation result data announced by the announcement agency 26. The announcement agency 26 includes a distribution server that distributes the power generation result data. The power generation result data acquisition unit 48A acquires the power generation result data announced by the announcement agency 26 via the communication system 7.

The usage amount calculation unit 48B calculates a usage amount of the electric power used to charge the battery 31 of the work machine 2. The usage amount of the electric power used to charge the battery 31 includes a first usage amount representing the usage amount of the first electric power used to charge the battery 31, and a second usage amount representing the usage amount of the second electric power used to charge the battery 31. The usage amount calculation unit 48B calculates the first usage amount representing the usage amount of the first electric power used to charge the battery 31 of the work machine 2, and the second usage amount representing the usage amount of the second electric power used to charge the battery 31.

The usage amount calculation unit 48B calculates the first usage amount and the second usage amount on the basis of the power generation result data. The usage amount calculation unit 48B can calculate the first usage amount representing the usage amount of the first electric power used to charge the battery 31 on the basis of the first power generation result data including the result value of the power generation amount and the first ratio of the first electric power, and a charging time and a charging period of the battery 31 that uses the charging station 23. The usage amount calculation unit 48B can calculate the second usage amount representing the usage amount of the second electric power used to charge the battery 31 on the basis of the second power generation result data including the result value of the power generation amount and the second ratio of the second electric power, and the charging time and the charging period of the battery 31 that uses the charging station 23.

The usage amount calculation unit 48B records the calculated first usage amount and second usage amount. In the embodiment, the usage amount calculation unit 48B causes a usage amount storage unit 50A of the storage 50 to store the calculated first usage amount and second usage amount. Furthermore, the usage amount calculation unit 48B transmits the calculated first usage amount and second usage amount to the management server 8.

The emission amount calculation unit 48C calculates an emission amount of carbon dioxide due to charging of the battery 31 on the basis of a designated carbon dioxide emission amount calculation method, the first usage amount, and the second usage amount. The emission amount of carbon dioxide includes a carbon dioxide conversion emission amount of greenhouse gas. The emission amount of carbon dioxide is calculated on the basis of an activity amount, an emission factor, and a Global Warming Potential (GWP). The activity amount includes the usage amounts (the first usage amount and the second usage amount) of the electric power used to charge the battery 31. The emission factor refers to a carbon dioxide emission amount per activity amount.

As the carbon dioxide emission amount calculation method, a method for calculating Scope 1 (direct emission amount), a method for calculating Scope 2 (indirect emission amount), and a method for calculating Scope 3 (other emission amounts) are exemplified.

The emission amount calculation unit 48C records the calculated emission amount of carbon dioxide. The emission amount calculation unit 48C records the emission amount of carbon dioxide emitted when the battery 31 is charged. The emission amount calculation unit 48C records the emission amount of carbon dioxide emitted when the work machine 2 operates. In the embodiment, the emission amount calculation unit 48C causes the emission amount storage unit 50B of the storage 50 to store the calculated emission amount of carbon dioxide. Furthermore, the emission amount calculation unit 48C transmits the calculated emission amount of carbon dioxide to the management server 8.

### Management Method

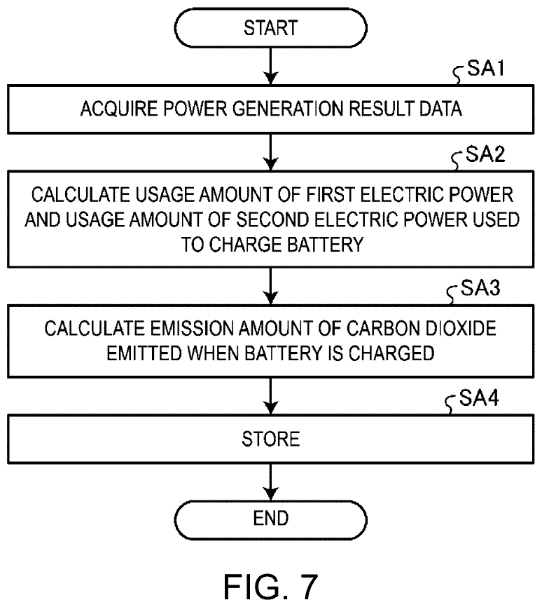

FIG. 7 is a flowchart illustrating the method for calculating the emission amount of carbon dioxide due to charging of the battery 31 according to the embodiment. The power generation result data acquisition unit 48A acquires the power generation result data from the announcement agency 26 (step SA1).

The usage amount calculation unit 48B calculates the first usage amount representing the usage amount of the first electric power and the second usage amount representing the usage amount of the second electric power, which are used to charge the battery 31, on the basis of the power generation result data acquired in step SA1. The usage amount calculation unit 48B calculates the first usage amount on the basis of the first power generation result data including the result value of the power generation amount and the first ratio of the first electric power, and the charging time and the charging period of the battery 31 that uses the charging station 23. The usage amount calculation unit 48B calculates the second usage amount on the basis of the second power generation result data including the result value of the power generation amount and the second ratio of the second electric power, and the charging time and the charging period of the battery 31 that uses the charging station 23 (step SA2).

The emission amount calculation unit 48C calculates the emission amount of carbon dioxide emitted when the battery 31 is charged, on the basis of the designated carbon dioxide emission amount calculation method, and the first usage amount and the second usage amount calculated in step SA2 (step SA3).

The first usage amount and the second usage amount calculated in step SA2 are stored in the usage amount storage unit 50A. The emission amount of carbon dioxide calculated in step SA3 is stored in the emission amount storage unit 50B. The first usage amount and the second usage amount calculated in step SA2 are transmitted from the in-vehicle controller 40 to the management server 8 via the communication system 7. The emission amount of carbon dioxide calculated in step SA3 is transmitted from the in-vehicle controller 40 to the management server 8 via the communication system 7 (step SA4).

The management server 8 stores the first usage amount, the second usage amount, and the emission amount of carbon dioxide. The emission amount of carbon dioxide stored in the management server 8 may be reported to the administrative agency.

### Effects

As described above, according to the embodiment, the processor 48 calculates the usage amount of the first electric power and the usage amount of the second electric power used to charge the battery 31 of the work machine 2. The carbon dioxide is emitted at the time of power generation of the first electric power, and the carbon dioxide is not emitted at the time of power generation of the second electric power. By calculating the respective usage amounts of the first electric power and the second electric power used to charge the battery 31, or the ratio of the first electric power and the second electric power used to charge the battery 31, how much greenhouse gas is emitted due to use of the work machine 2 including the battery 31 is recognized.

### Other Embodiments

In the above-described embodiment, the usage amount of the first electric power and the usage amount of the second electric power used to charge the battery 31 of the excavator 2A are calculated. The usage amount of the first electric power and the usage amount of the second electric power used to charge the battery 31 of the bulldozer 2B may be calculated. The usage amount of the first electric power and the usage amount of the second electric power used to charge the battery 31 of the dump truck 2C may be calculated.

### REFERENCE SIGNS LIST

1 Management system, 2 Work machine, 2A Excavator, 2B Bulldozer, 2C Dump truck, 3 Work site, 4 Remote operation room, 5 Information terminal, 6 Remote operation device, 7 Communication system, 8 Management server, 9 Revolving body, 10 Traveling body, 10A Crawler track, 11 Work implement, 11A Boom, 11B Arm, 11C Bucket, 12 Work implement cylinder, 12A Boom cylinder, 12B Arm cylinder, 12C Bucket cylinder, 20 Power plant, 21 First power plant, 22 Second power plant, 23 Charging station, 24 Power transmission facility, 25 Power supply area, 25A First area, 25B Second area, 26 Announcement agency, 30 Control system, 31 Battery, 32 Charging device, 33 DC/DC converter, 34 Inverter, 35 Electric motor, 36 Hydraulic pump, 37 Main valve, 38 Hydraulic actuator, 40 In-vehicle controller, 43 Communication device, 48 Processor, 48A Power generation result data acquisition unit, 48B Usage amount calculation unit, 48C Emission amount calculation unit, 49 Main memory, 50 Storage, 50A Usage amount storage unit, 50B Emission amount storage unit, 51 Interface

1. A management system for a work machine, comprising:
a processor, wherein
the processor
calculates a usage amount of electric power used to charge a battery of the work machine, and
causes a storage device to store the usage amount,
the electric power comprises one or both of first electric power for emitting a first amount of carbon dioxide to generate a unit amount of electric power, and second electric power for emitting a second amount of carbon dioxide smaller than the first amount to generate the unit amount of electric power, and
the usage amount includes a first usage amount representing a usage amount of the first electric power used to charge the battery, and a second usage amount representing a usage amount of the second electric power used to charge the battery.

2. The management system for the work machine according to claim 1, wherein the first electric power is generated using exhaustible energy, and the second electric power is generated using renewable energy.

3. The management system for the work machine according to claim 2, wherein the processor
acquires power generation result data including first power generation result data representing, for each time interval, a result value of a power generation amount generated using the exhaustible energy, and second power generation result data representing, for each time interval, a result value of a power generation amount generated using the renewable energy, and
calculates the first usage amount and the second usage amount on a basis of the power generation result data.

4. The management system for the work machine according to claim 3, wherein the processor
calculates an emission amount of carbon dioxide due to the charging of the battery on a basis of a designated calculating method for a carbon dioxide emission amount, the first usage amount, and the second usage amount, and
causes the storage device to store the emission amount of the carbon dioxide.

5. A management method for a work machine, comprising:
calculating a usage amount of electric power used to charge a battery of the work machine; and
recording the usage amount, wherein
the electric power comprises one or both of first electric power for emitting a first amount of carbon dioxide to generate a unit amount of electric power, and second electric power for emitting a second amount of carbon dioxide smaller than the first amount to generate the unit amount of electric power, and
the usage amount includes a first usage amount representing a usage amount of the first electric power used to charge the battery, and a second usage amount representing a usage amount of the second electric power used to charge the battery.
